(19) United States
(12) Patent Application Publication
(10) Pub. No.: US 2016/0345470 A1
(43) Pub. Date: Nov. 24, 2016

(54) ELECTRONIC DEVICE AND HOUSING FOR ELECTRONIC DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YU-MING XIAO, Wuhan (CN); LIANG-CHIN WANG, New Taipei (TW); ZAN LI, Wuhan (CN); CHUAN LIN, Wuhan (CN)

(21) Appl. No.: 14/735,942

(22) Filed: Jun. 10, 2015

(30) Foreign Application Priority Data
May 19, 2015 (CN) 201510255283.9

(51) Int. Cl. H05K 9/00; H01L 23/552; H01L 23/04

(52) U.S. Cl. CPC H05K 9/002; H01L 23/04; H01L 23/552

(57) ABSTRACT

A housing of an electronic device to prevent an output of electromagnetic radiation includes a shell, a conducting layer, and two side plates. The shell can be made of non-conducting material. The conducting layer is attached to the shell. The two side plates can be made of conducting material. The two side plates are fixed to two ends of the shell and are in contact with the conducting layer. The housing of the electronic device is electrically conductive. An electronic device is also provided.

### CROSS-REFERENCE TO RELATED APPLICATIONS

This application claims priority to Chinese Patent Application No. 201510255283.9 filed on May 19, 2015, the contents of which are incorporated by reference herein.

### FIELD

The subject matter herein generally relates to a housing of an electronic device and an electronic device.

### BACKGROUND

When an electronic device works, the electronic device produces electromagnetic radiation which, without shielding, may damage human's body.

### BRIEF DESCRIPTION OF THE DRAWINGS

Implementations of the present technology will now be described, by way of example only, with reference to the attached figures.

FIG. 1 is an exploded, isometric view of one embodiment of a housing of an electronic device.

FIG. 2 is an assembled, isometric view of the housing of the electronic device of FIG. 1, a shell is removed from a base.

FIG. 3 is an enlarged view of a circled portion III of FIG. 2.

FIG. 4 is an assembled, isometric view of the housing of the electronic device of FIG. 1, the shell is fixed to the base.

FIG. 5 is a cross-sectional view of the housing of the electronic device, taken along line V-V of FIG. 4.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to a housing of an electronic device.

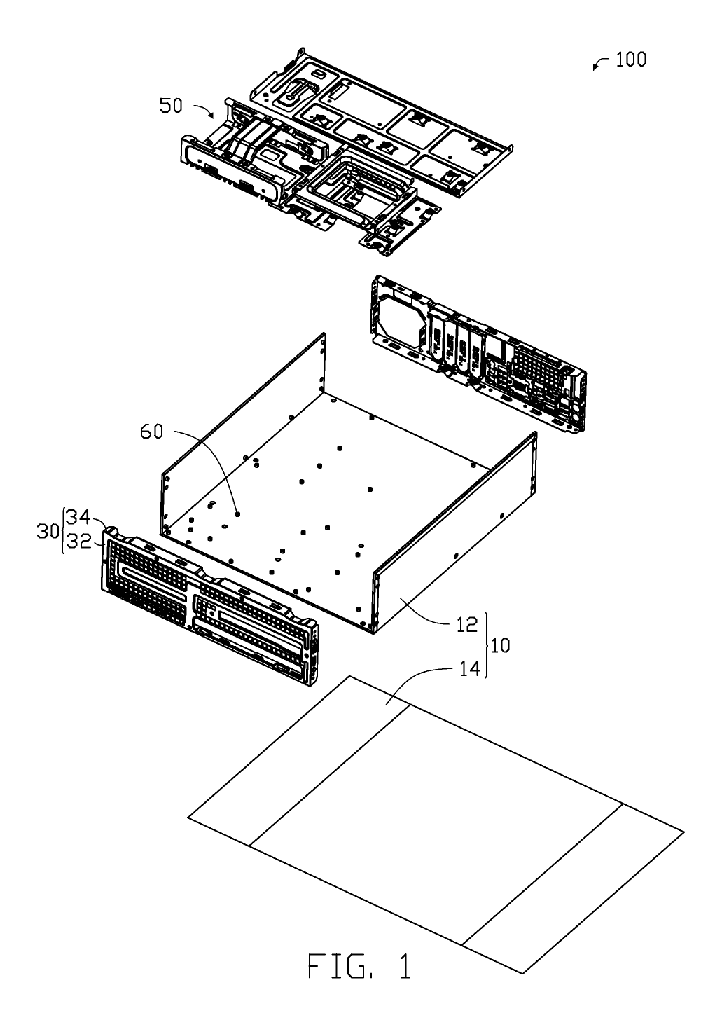

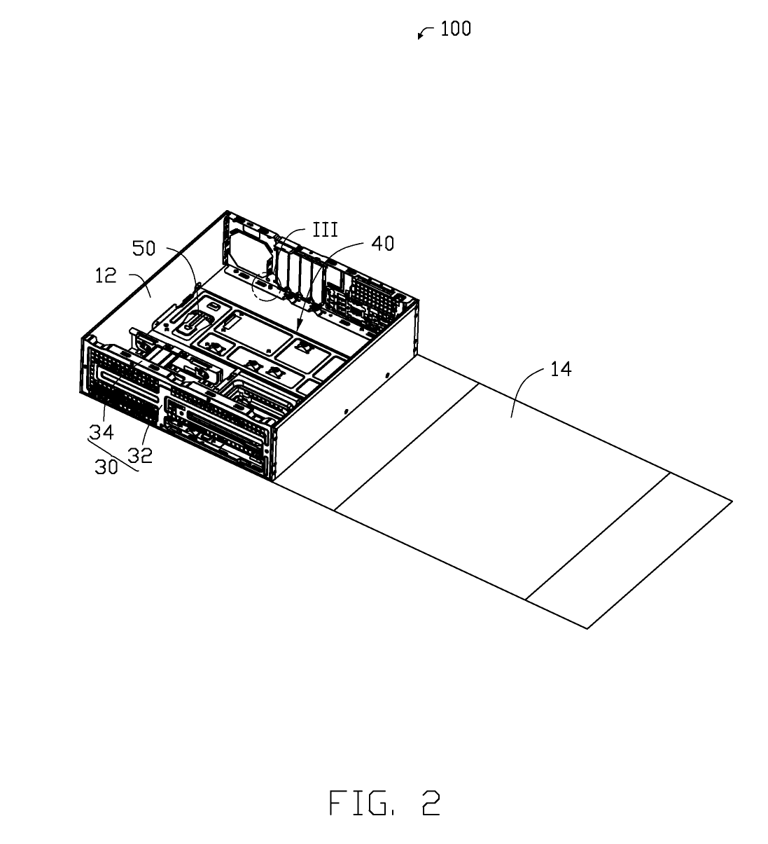

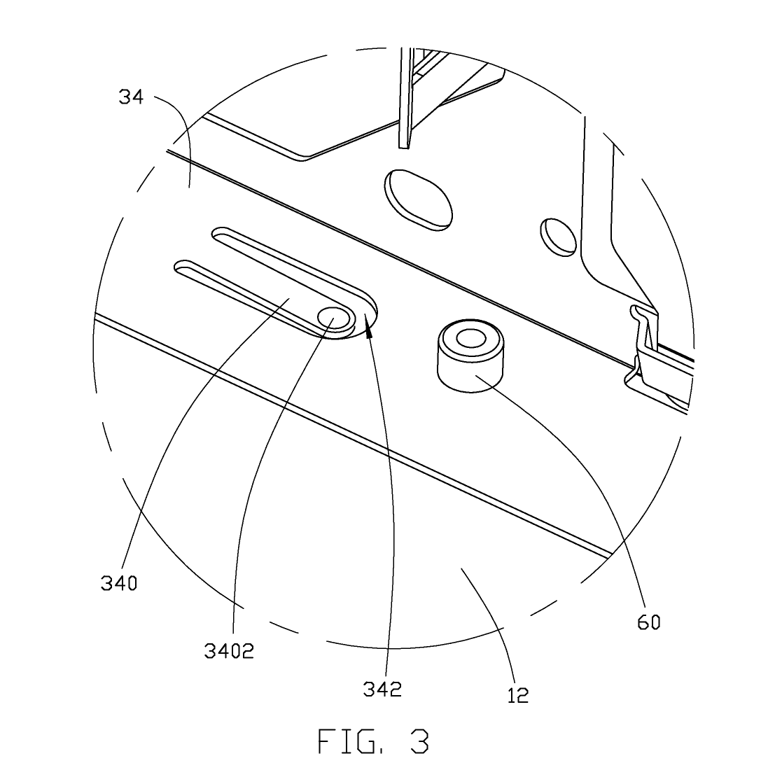

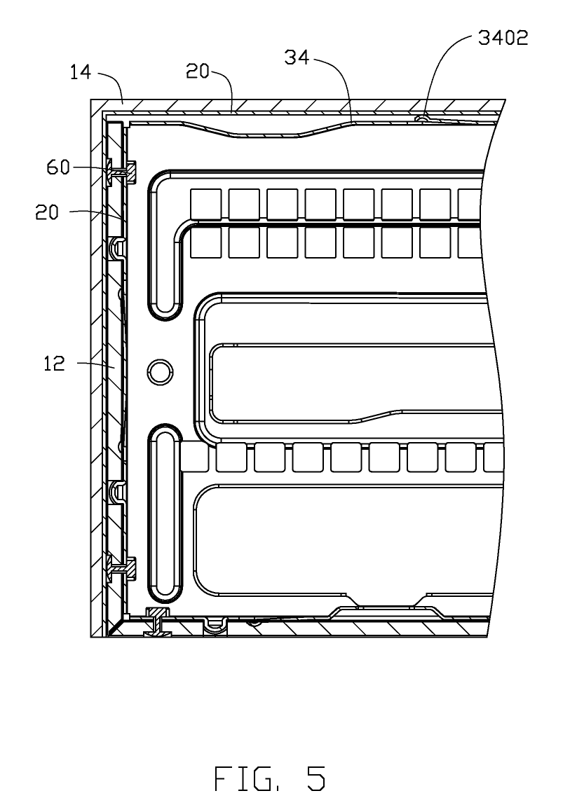

FIGS. 1-3 illustrate one embodiment of a housing of an electronic device 100. The housing 100 includes a shell 10, a conducting layer 20 (shown in FIG. 5), and two side plates 30.

The shell 10 includes a base 12 and a cover 14. The base 12 and the cover 14 can be made of non-conducting material. The non-conducting material can include fibrous material with a high density, or plastic. A cross section of the base 12 and the cover 14 can be substantially U-shaped. The conducting layer 20 can be coated or adhered to an inner surface of the base 12 and the cover 14. In one embodiment, the base 12 and the cover 14 can include paper material. A thickness of the paper can be greater than 1.5 mm. In one embodiment, an aluminized film is coated or adhered to opposing sides of the base 12 and the cover 14 to form the conducting layer 20. In another embodiment, an electromagnetic shield coating is coated on the base 12 and the cover 14 to form the conducting layer 20. A plurality of conductive particles can be mixed with a chemical reagent to form the electromagnetic shield coating.

The two side plates 30 can be made of conducting material. Each side plate 30 includes a body 32 and two side pieces 34. The two side pieces 34 are located on two sides of the body 32. In one embodiment, the two side pieces 34 are substantially parallel to each other. Each side piece 34 extends from the body 32 and is substantially perpendicular to the body 32. Each side piece 34 includes a plurality of spring pieces 340 and defines a plurality of grooves 342. The plurality of spring pieces 340 is located in the plurality of grooves 342. Each spring piece 340 includes a protrusion 3402. The protrusion 3402 is located on one end of the spring piece 340. In one embodiment, each groove 342 can be substantially U-shaped.

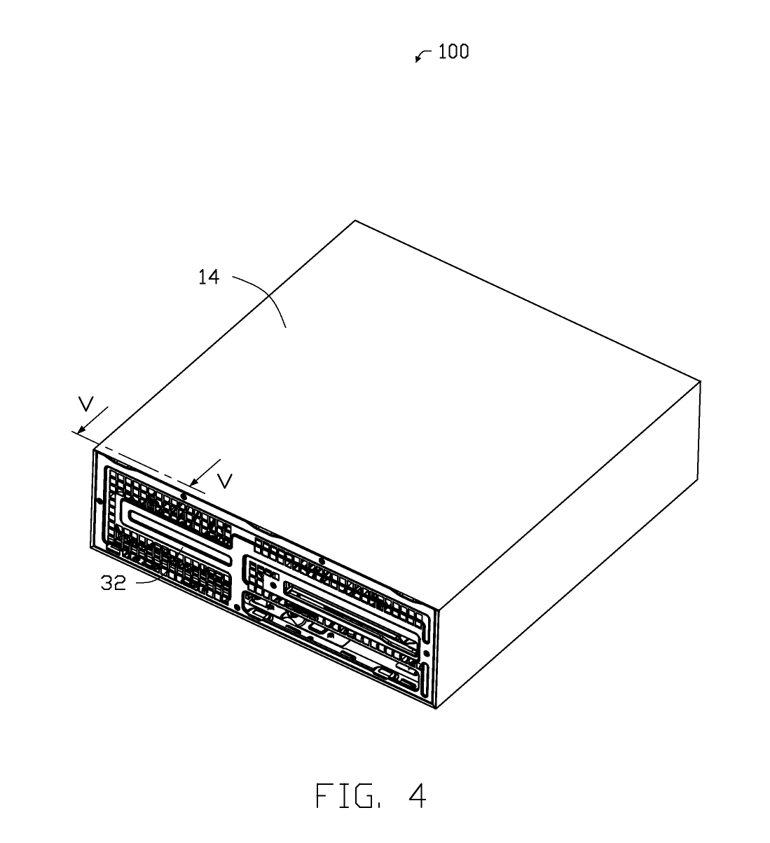

FIGS. 4-5 illustrate assembled views of the housing of the electronic device of FIG. 1. The side plates 30 are fixed to ends of the base 12. The protrusion 3402 of the spring piece 340 is attached to the conducting layer 20 of the base 12. The two side plates 30 are electrically connected to the base 12. The cover 14 is fixed to the base 12. The conducting layer 20 of the cover 14 is attached to the protrusion 3402 of the two side plates 30. The cover 14 is electrically connected to the two side plates 30. The cover 14, the base 12, and the two side plates 30 cooperatively define a shielded space 40.

When the housing 100 is functioning, a plurality of metallic components 50 is fixed to the base 12 via a plurality of fixing members 60. The plurality of metallic components 50 is attached to the conducting layer 20 of the base 12. The plurality of metallic components 50 is received in the shielded space 40. The plurality of metallic components 50 prevents leakage of electromagnetic radiation from the housing 100.

The embodiments shown and described above are only examples. Many details are often found in the art such as the other features of the housing of the electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A housing of an electronic device comprising:
a shell made of non-conducting material;
a conducting layer attached to the shell;
a side plate comprising conducting material; and
wherein the side plate is fixed to the shell and contacts with the conducting layer, and the side plate and the shell are electrically conductive; and the conducting layer is located within a space surrounded cooperatively by the shell and the side plate.

2. The housing of claim 1, wherein the shell comprises a base and a cover, the conducting layer is attached to an inner surface of the cover and the base, and the cover is electrically connected to the base via the side plate.

3. The housing of claim 2, wherein the conducting layer attached to the base and the cover and the side plate cooperatively define a shielded space to prevent electromagnetic radiation from leaking.

4. The housing of claim 2, wherein the side plate comprises two side pieces, each side piece comprises a plurality of protrusions, the plurality of protrusions of one of the two side pieces is attached to the conducting layer of the base, and the side plate is electrically connected to the base.

5. The housing of claim 4, wherein the plurality of protrusions of another of the two side pieces is attached to the conducting layer of the cover, and the side plate is electrically connected to the cover.

6. The housing of claim 2, wherein a cross section of the base is substantially U-shaped.

7. The housing of claim 2, wherein a cross section of the cover is substantially U-shaped.

8. The housing of claim 1, wherein the conducting layer is made of aluminized film.

9. The housing of claim 1, wherein an electromagnetic shield coating is coated on the shell to form the conducting layer.

10. The housing of claim 1, wherein the shell is made of paper material, and a thickness of the paper is greater than 1.5 mm.

11. An electronic device comprising:
a shell made of non-conducting material;
a conducting layer attached to the shell;
a side plate comprising conducting material;
a plurality of metallic components; and
wherein the side plate and the plurality of metallic components are fixed to the shell and contacts with the conducting layer, and the side plate and the shell are electrically conductive; and the conducting layer is located within a space surrounded cooperatively by the shell and the side plate.

12. The electronic device of claim 11, wherein the shell comprises a base and a cover, the conducting layer is attached to an inner surface of the base and the cover, and the cover is electrically connected to the base via the side plate.

13. The electronic device of claim 12, wherein the conducting layer attached to the base and the cover and the side plate cooperatively define a shielded space to prevent electromagnetic radiation from leaking.

14. The electronic device of claim 12, wherein the side plate comprises two side pieces, each side piece comprises a plurality of protrusions, the plurality of protrusions of one of the two side pieces is attached to the conducting layer of the base, and the side plate is electrically connected to the base.

15. The electronic device of claim 14, wherein the plurality of protrusions of another of the two side pieces is attached to the conducting layer of the cover, and the side plate is electrically connected to the cover.

16. The electronic device of claim 12, wherein a cross section of the base is substantially U-shaped.

17. The electronic device of claim 12, wherein a cross section of the cover is substantially U-shaped.

18. The electronic device of claim 11, wherein the conducting layer is made of aluminized film.

19. The electronic device of claim 11, wherein an electromagnetic shield coating is coated on the shell to form the conducting layer.

20. A housing of an electronic device comprising:
a U-shaped base of non-conducting material;
a conducting layer attached to lateral sides of the U-shaped base;
a U-shaped cover of non-conducting material, inversely mounted on the base to define with the base a shell with four sides and two openings at opposite ends;
first and second end plates of conductive material mounted in the two openings; and
the first and second end plates being electrically connected to the cover.
